(19) United States
(12) Patent Application Publication
(10) Pub. No.: US 2006/0131709 A1
(43) Pub. Date: Jun. 22, 2006

(54) Semiconductor die positioning system and a method of bonding a semiconductor die to a substrate

(76) Inventors: Michael Roger Caron, Cumberland Foreside, ME (US); Samuel V. Nablo, Acton, MA (US); John Paul Frazier, Scarborough, ME (US); John Vincent Vogt, Scarborough, ME (US)

Correspondence Address: Kevin M. Farrell;Pierce Atwood, Suite 350, One New Hampshire Avenue, Portsmouth, NH, 03801, US

(21) Appl. No.: 11/019,836

(22) Filed: Dec. 21, 2004

(51) Int. Cl. H01L 23/12; H01L 21/58

(52) U.S. Cl. 257/678; 438/118; 438/455; 257/690

(57) ABSTRACT

The present invention describes a process for bonding a semiconductor die to a selected substrate, including the formation of a die positioning structure on the substrate to receive and secure the semiconductor die. The substrate is selected from a number of materials, the properties of which render it penetrable by electron beam radiation. The die positioning structure is a second material which is electron beam curable, and which is deposited and cured at high speed on the substrate in a novel fashion in accordance with the present invention in a highly efficient reproducible and economical manner.

### BACKGROUND OF THE INVENTION

1. Field of the Invention

The present invention relates generally to the field of semiconductor packaging, and more specifically to the positioning and bonding of a semiconductor die to a selected substrate designated for use in any one of a number of fields, including the manufacture of integrated circuits.

2. Description of the Related Art

In 1964, Gordon Moore predicted that the number of devices on a single circuit would double every year. This prediction, known as Moore's law, has proven largely accurate, and the resultant growth in the semiconductor industry has been readily apparent. In the early 1960's, the focus of scientists and engineers was on the so-called small-scale integration (SSI), involving between 2 and 50 components per integrated circuit. As of the mid 1990's, the problems to be solved were with regard to ultra large-scale integration (ULSI), involving greater than one million components per integrated circuit.

As complexity in the integrated circuit field increased, one particular aspect of circuit manufacture has also grown in sophistication. The fabrication and packaging of the semiconductor components of the integrated circuits, known as die or dice, has become the focus of many technology companies. The dice, generally made from silicon, are formed through a process that is familiar to those skilled in the art. First, silicon crystals are grown into cylindrical structures. Silicon wafers are then sliced from the original structure and then run through the fabrication process. The fabrication process includes coating the wafers with numerous other materials to create the type of electrical device sought, for example a metal-oxide-silicon (MOS) semiconductor. The dice are then tested, and the active dice are then picked out for placement.

The active dice are then packaged for use in a number of applications. For example, dice are often placed individually into a “package”, which is typically a device with substantial leads that is then connected to a printed circuit board (PCB). Alternatively, dice are sometimes packaged into what are known as multi-chip modules (MCM's,) or hybrid circuits, which are electrical devices having both solid-state and conventional components such as capacitors and resistors. Lastly, dice may be deposited directly on the PCB, known as chip-on-board (COB). Moreover, semiconductor materials are used for a host of other applications, including for example photodetectors and light emitting diodes, which must be packaged with increasing regularity and precision. The exact form of the final package in which the dice are located depends upon a number of factors, including the application, the necessary “chip density”, the operating environment of the circuit, and the cost considerations of the end user.

Nevertheless, a significant and recurring problem faced by semiconductor chip manufacturers is the inaccurate or failed placement of the die in the package. Given the relatively small size of the die, and the trends toward even smaller solid-state components, the accurate and successful bonding of the die to the substrate and electrical leads is a necessary condition for further innovations in the integrated circuit and semiconductor packaging field. A misplaced die can render an entire circuit inoperable, which can result in costly replacements, lower production yields, and higher costs in the manufacture of integrated circuits, all of which must be borne by the end user of the product.

Given the foregoing, there is a need in the art for a reliable, cost-effective, and easily replicated method of bonding a semiconductor die to a substrate that is usable over a range of commercial applications. In particular, there is a need for a method of bonding a die to a substrate that can be utilized across a range of potential substrates including printed circuit boards and ceramic or plastic packages.. Moreover, there is a need for a novel production method that is capable of large-scale cost effective production of solid-state electronic components with reliable testing parameters and a high production yield.

### SUMMARY OF THE INVENTION

Accordingly, the present invention includes an efficient, reliable, and easily reproduced die positioning system and a method of making the same. The die positioning system of the present invention includes a substrate having at least one conductive electrical lead thereon and a die positioning structure disposed on the substrate. The die positioning structure is cast and cured specifically for receiving a semiconductor die of the type typically used in electronic, optoelectronic and other applications. The silicon die is electrically connected to the conductive electrical leads through at least one bond. The die positioning system of the present invention is an improved system for the manufacture and packaging of semiconductor products. The formation and placement of the die positioning structure can be reproduced with high fidelity, greatly streamlining the current packaging methods of the semiconductor industry.

The novel die positioning system of the present invention is the result of an improved method of manufacture in the semiconductor industry. The method includes a number of acts, including providing a substrate with at least one electrical lead and a second material. The substrate is generally of a dielectric material and hydrophobic, and should preferably be of low stopping power for electron beam radiation. The second material is curable by electron beam radiation, and is disposed on the substrate through a pressing or casting mechanism that forms the die positioning structure discussed above. Once the die positioning structure is cured and affixed to the substrate, a semiconductor die is positioned within the die positioning structure and connected to the electrical leads through at least one bonding point. At this time, a manufacturer may provide a test signal receivable by the electrical leads to test the electrical connections of the die positioning system. Once the operability of the die positioning system is confirmed, a protective cap or coating may be disposed over the semiconductor die and the die positioning structure to increase the resiliency, ruggedness and abrasive resistance of the package.

The method of the present invention can be utilized to produce any number of electronic devices that may include a substrate with electrical leads, the electron-beam curable die positioning structure, and a semiconductor die of predetermined qualities. The electronic devices of the present invention are suitable for a range of applications across the semiconductor field, including the packaging of electrical components, RFID tags, optoelectronic devices and the like.

The foregoing is intended as a summary of the novel and useful features of the present invention. Further aspects, features and advantages of the invention will become apparent from consideration of the following Detailed Description and the appended Claims when taken in connection with the accompanying Drawings.

### BRIEF DESCRIPTION OF THE DRAWINGS

FIG. 1 is an oblique perspective view of a die positioning structure in accordance with the present invention.

FIG. 2 is a perspective view of a typical semiconductor die usable in accordance with the present invention.

FIG. 3 is a cross-sectional view of the die positioning structure in accordance with one embodiment of the present invention.

FIG. 4 is an oblique perspective view of a die positioning structure in accordance with the present invention.

FIG. 5 is a plan view of a package for use in an integrated circuit incorporating the die positioning structure of the present invention.

FIG. 6 is a cross-sectional view of a negative cast usable in the making of the die positioning structure in accordance with the present invention.

FIG. 7 is a plan view of a negative cast usable in making the die positioning structure in accordance with the present invention.

FIG. 8 is a flow chart depicting a method of making a die positioning structure in accordance with the present invention.

### DETAILED DESCRIPTION OF THE INVENTION

Two embodiments of the invention to accommodate the semiconductor die in a normal (bond pads up) and flip chip (bond pads down) orientation are presented here.

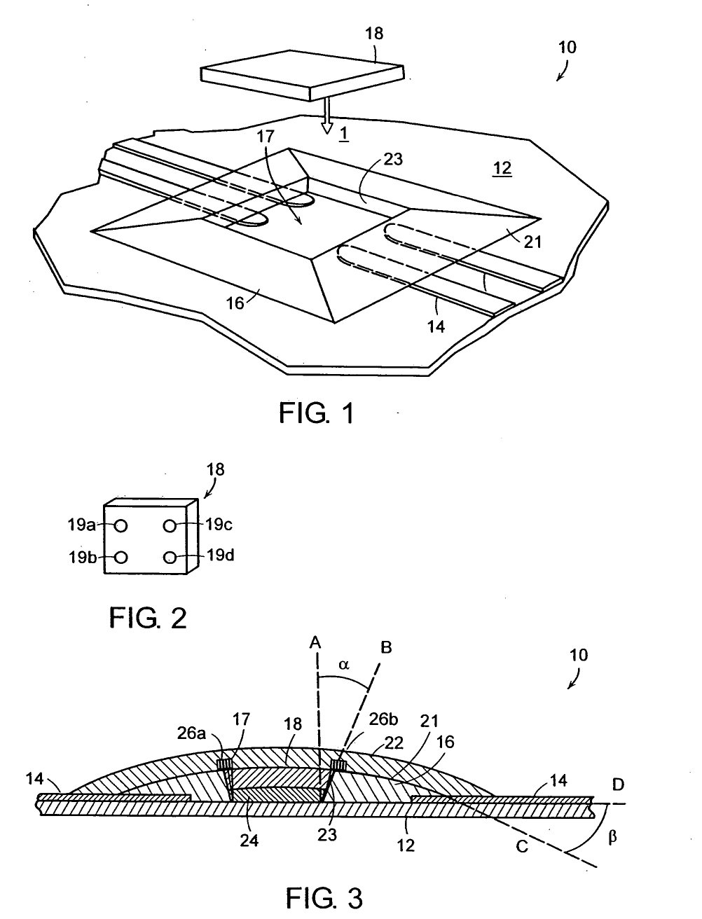

FIG. 1 is a perspective view of a die positioning system 10 in accordance with a preferred embodiment of the present invention. The die positioning system 10 includes a substrate 12 having a plurality of electrical leads 14 formed thereon. A die positioning structure 16 is disposed on the substrate 12 and substantially covers the plurality of electrical leads 14. The die positioning structure 16 defines in part an outer slope 21 and an inner slope 23. The die positioning structure 16 also defines a die positioning cavity 17, which allows selective access to the plurality of electrical leads 14. The die positioning cavity 17 is adapted to receive a semiconductor die 18, which may be placed into the die positioning cavity 17 along the direction of arrow 1.

The substrate 12 should be of low stopping power (such as a hydrocarbon film or paper) for energetic electrons in order to minimize the electron energy required to fully penetrate the substrate and the polymer in the die positioning system negative. This need arises due to the normal curing of the die positioning structure against a metal platen or drum carrying the negative engraving. For example, with a 250 kilo-electron volt (keV) electron processor, total thickness to be penetrated may be up to 350 g/m² (or 350 μm of unit density polymer/film), while a 300 keV system can handle thicknesses to 500 g/m². Thicker structures can, of course, be handled by higher energy electron processors, but the ease of their adaptation to a self-shielded, in-line production system becomes more complex and costly with higher electron energies (and the higher energy x-rays which they produce and for which shielding is required).

The die positioning structure 16 is preferably comprised of an electron-beam (E-beam) curable material. E-beam radiation is a non-thermal method that uses high-energy electrons as the ionizing radiation to initiate polymerization and cross-linking reactions at controlled dose rates in polymeric materials. Electron curing has been employed in the converting industry for several decades—typically for the high speed curing of thin films, coatings or laminating adhesives. Some polymers (e.g., polyethylene) naturally cross-link via e-beam treatment, while others such as most high-performance epoxies and acrylated copolymers, require modification to initiate curing. Similarly, these formulations, without the photoinitiator, can be used for the room temperature electron cure.

E-beam curing has several advantages over conventional thermal curing methods including: improved product quality/performance; reduced environmental, safety, and health concerns; improved material handling; ability to combine various materials and functions in a single operation; ability to utilize lower cost tooling; capability to produce unique parts that cannot be fabricated any other way; reduced energy consumption; and greatly reduced cure times. In the context of the present invention, a particularly important advantage is the ability to cure at higher speeds at near room temperature. Current thermal curing techniques for connecting bond pads to a substrate require exposure to temperatures within the range of 150 to 160 degrees C. for several seconds. Epoxy Technology (Billerica, Mass. 01821) offers a line of products described as UV-curable adhesives which, when modified, would be suitable for use in connection with e-beam curing methods. More specifically, the photoinitiator can be removed from the UV-curable adhesive for use in connection with e-beam curing methods. One skilled in the art would be familiar with a variety of other suitable e-beam curable polymer formulations.

In a preferred embodiment, the die positioning structure 16 is comprised of a material that is hydrophobic, and thus capable of seating the semiconductor die 18 while preventing any electromagnetic or moisture-caused interference with the operation of the die positioning system 10. Suitable materials include acrylates, urethanes, resins and epoxies that undergo rapid polymerization when exposed to electron beam radiation. In the flip-chip (bond pads down) embodiment, the die positioning structure 16 is preferably a strong insulator. A preferred insulating material is acrylated urethane, which has the necessary adhesive properties to properly bond to the substrate 12 while maintaining a degree of flexibility and providing an adequate coefficient of friction suitable for receiving and holding the semiconductor die 18.

FIG. 2 is an oblique perspective view of a semiconductor die 18 illustrating a plurality of contact points 19a, 19b, 19c, 19d that are electrically conductive and connectable to the electrical leads 14a, 14b, 14c, 14d shown as part of the die positioning system 10. The semiconductor die 18 may be comprised of silicon, gallium arsenide, or any other suitable material depending on the application. For example, in a typical electronic package, it is customary for the semiconductor die 18 to consist of silicon that has been doped and coated several times with different metals and semiconductors to form the desired end product. On the other hand, in various optoelectronic applications, it may be the case that the semiconductor die 18 consists of gallium arsenide or some other material that is doped and coated with different metals and semiconductors. It is understood, however, that the present invention is an improvement across a range of semiconductor uses, and thus this description should not be interpreted as limiting the type of semiconductor material that is placed in the die positioning system 10.

FIG. 3 is a cross-sectional view of a die positioning system 10 in accordance with the present invention. In a preferred embodiment, the die positioning structure 16 defines the die-positioning cavity 17. The depth of the die positioning cavity 17 preferably approximates the thickness of the semiconductor die 19 and any underfill that may be employed.

The die positioning cavity 17 defines an inner slope 23 that is angled relative to the surface of the substrate 12. Specifically, a first line A is defined normal to the surface of the substrate 12. A second line B is defined coplanar with the surface of the inner slope 23, and the angle between A and B is designated α. In a preferred embodiment, the angle a is between 10 and 20 degrees, and is most preferably about 15 degrees. The angled face of the inner slope 23 allows for improved reliability and accuracy when positioning the semiconductor die 18 into the die positioning cavity 17.

The die positioning structure 16 also defines at least one outer surface 21 that is gradually sloped relative to the surface of the substrate 12. A third line C is defined coplanar with the surface of the outer surface 21. A fourth line D is defined coplanar with the surface of the substrate 12, and the angle between C and D is designated β. In a preferred embodiment, the angle β is between 20 and 40 degrees, and is most preferably about 30 degrees. The angled face of the outer surface 21 allows for improved resistance to wear and tear to the die positioning system 10 arising from print head or transport roller contact, and reduces the probability that any shearing forces or friction will dislodge the semiconductor die 18 from its connection to the electrical leads 14. Other contours for the die positioning system 16 will be obvious to those skilled in the art.

As shown in FIG. 3, the die positioning system 10 also provides for an alternate embodiment in which there is an underfill 24 disposed within the die positioning cavity 17 below the semiconductor die 18. The semiconductor die 18 is then conductively connected with its bond pads up at bonds 26a, 26b to the electrical leads 14. This connection can be realized via the addition of a conductive path. For a non-conducting die positioning structure the conductive path could be a printed line from the bond pad to the electrical lead 14. In the case of a conductive die positioning structure, the required addition is only a conductive bond 26a, 26b from the bond pad to the die positioning structure.

An embodiment with an electrically conductive die positioning structure 16 can be the product of a conductive material that is E-beam curable. This particular bonding scheme provides all the benefits of E-beam curing discussed in detail above. A suitable material for the bonding of the pads to the circuit leads in this particular embodiment is a metal-doped epoxy. Preferably, the die positioning structure 16 is treated with blocking pigments to optically shield the semiconductor die 18 from photovoltaic action.

FIG. 3 also shows a protective cap 22, preferably composed of non-conductive material, disposed over the die positioning structure 16, the semiconductor die 18, and the bonds 26a, 26b to increase the resiliency and abrasion resistance of the die positioning system 10. Preferably, the protective cap 22 is treated with a blocking pigment to optically shield the die from photovoltaic action.

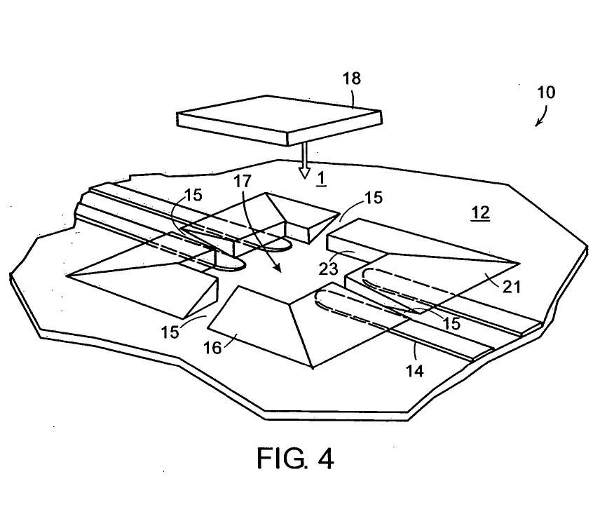

As shown in FIG. 4, in the case of a conductive die positioning structure 16, sectional gaps 15 within the die positioning structure 16 are required to prevent the formation of direct conductive connections between electrical leads 14. It will be understood by those skilled in the art that in the embodiments in which the die positioning structure 16 is conductive, such as the flip-chip embodiment described herein, the die positioning structure 16 would have sufficient electrical isolation provided by the sectional gaps 15 to ensure a sound electrical connection to the respective electrical leads 14. Thus, in the particular case demonstrated in FIG. 4, as there is a total of four electrical leads 14, the die positioning structure 16 must be divided into four portions by the sectional gaps 15.

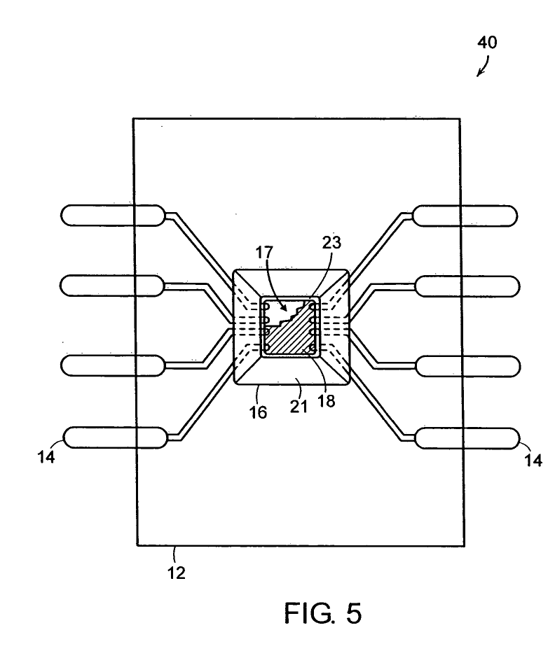

FIG. 5 is a plan view of an electronic device 40 in accordance with the present invention. The electronic device 40 includes a substrate 12 having a plurality of electrical leads 14 formed thereon. A die positioning structure 16 is disposed on the substrate 12 and substantially covers the plurality of electrical leads 14. The die positioning structure 16 defines in part an outer slope 21 and an inner slope 23. The die positioning structure 16 also defines a die positioning cavity 17, which allows selective access to the plurality of electrical leads 14. The die positioning cavity 17 is adapted to receive a semiconductor die 18, which is partially cut-away in FIG. 5 to show the definition of the die positioning cavity 17 and the electrical leads 14.

The electronic device 40 as depicted in FIG. 5 is representative in nature only, and is not meant to limit the potential application of the die positioning system 10 shown in FIGS. 1-4. On the contrary, the term electronic device 40 as used in the present application is defined as any device that utilizes a semiconductor material for the receipt, emission, transmission, or processing of electrical current or electromagnetic radiation. Examples of an electronic device 40 includes, but are not limited to, integrated circuits, photodiodes, light emitting diodes and radio frequency identification tags.

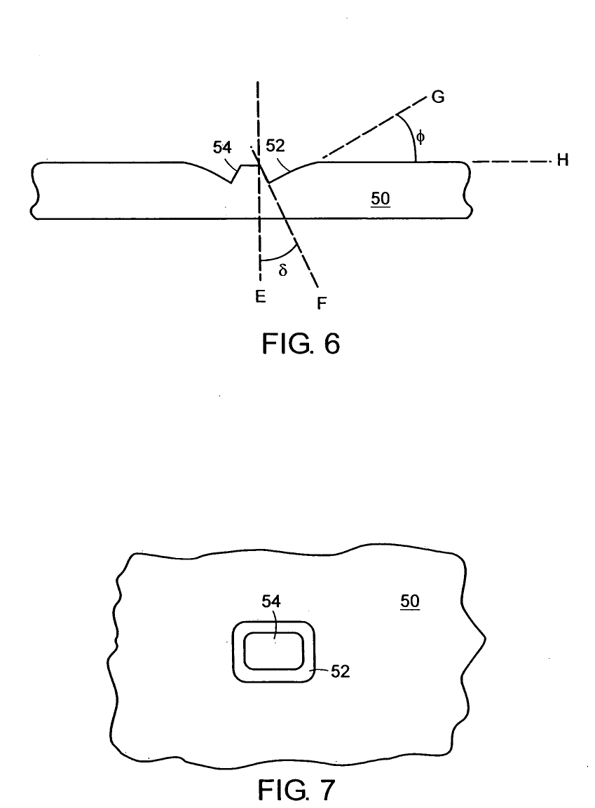

FIG. 6 is a cross-sectional view of a preferred negative cast 50 usable in the making of a die positioning system 10. FIG. 7 is a plan view of the preferred negative cast 50. The shape defined by the negative cast 50 is the inverse of the shape defined by the die positioning structure 16, discussed above in detail. The negative cast 50 defines an inner bank 54 and an outer bank 52. Line E is defined as normal to the surface of the negative cast 50. Line F is defined as coplanar with the surface of the inner bank 54, and the angle between lines E and F is designated δ. The angle δ is preferably between 10 and 20 degrees, and most preferably it is approximately 15 degrees.

The outer bank 52 of the negative cast 50 is more gradually sloped in order to cast a die positioning structure 16 that has an outer bank 21 of the characteristics shown in FIG. 3. A line H is defined as coplanar with the negative cast 50. A line G is defined as coplanar with the outer bank 52, and the angle between lines G and H is designated φ. The angle φ is preferably between 20 and 40 degrees, and is most preferably approximately 30 degrees.

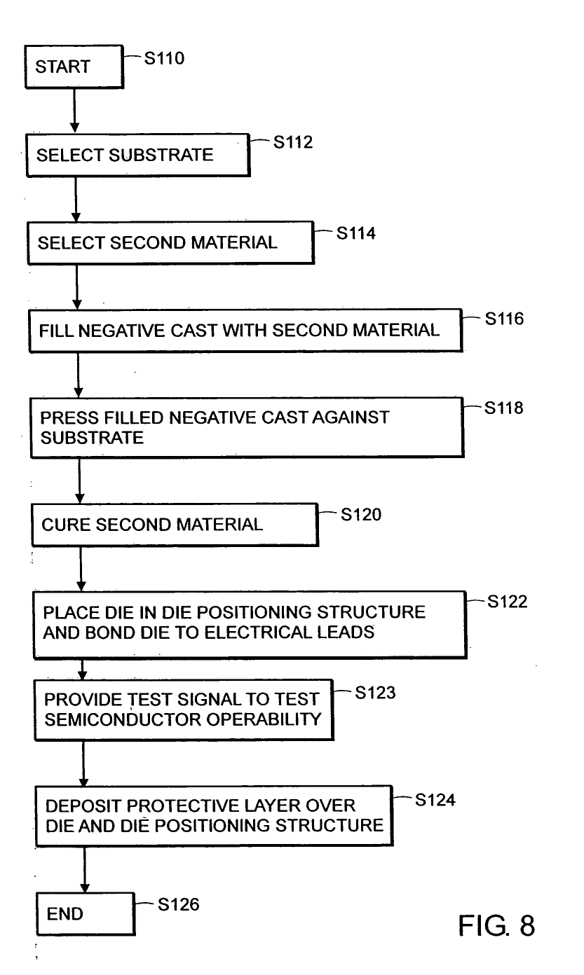

FIG. 8 is a flow chart depicting a method of bonding a semiconductor die 18 to a substrate 12 in accordance with the preferred embodiments of the present invention.

Starting at step S110, the method of the present invention provides that a substrate 12 is selected in step S112. As discussed above with reference to the die positioning system 10, the substrate 12 can be any number of materials that will permit the E-beam curing of the die positioning structure 16. As previously noted, the substrate 12 should be a poor absorber of electron beam radiation, as well as adaptable to a plurality of packaging options covering a wide range of commercial uses.

In step S114, a second material is selected, the second material being adapted for use as the die positioning structure 16 discussed above. The die positioning structure 16 is preferably comprised of a material that is hydrophobic and capable of securely seating the semiconductor die 18, while preventing any electromagnetic or moisture interference with the operation of the die positioning system 10. In preferred embodiments, the second material is preferably an acrylate, epoxy, or metal-doped epoxy. Lastly, the die positioning structure 16 is preferably treated with blocking pigments to optically shield the semiconductor die 18 from photovoltaic action.

In step S116, the negative cast 50 of the die positioning structure 16 is filled with a suitable amount of the second material. The filling process may include knifing the second material into the negative cast 50 so as to eliminate any excess second material. In step S118, the filled negative cast 50 is positioned against the surface of a selected substrate 12 such that a die positioning structure 16 will be formed on the surface of the substrate 12 through E-beam curing.

Once the second material is pressed into a die positioning structure 16 in step S118, the second material is cured in step S120. The curing step comprises using electron beam radiation to polymerize the second material and render the die positioning structure 16. In a preferred embodiment, the step of curing the second material comprises using an electron beam with energy in the range of 100 to 300 kilo-electron volts (keV). Most preferably, the energy of the curing electron beam is approximately 200 keV, which is adequate for processing substrate die positioning structure polymer thicknesses up to 200 g/m², typical of many tag requirements.

Following the electron beam curing of the second material in step S120, the semiconductor die 18 is bonded to the die positioning structure 16 and the electrical leads 14 in step S122.

In step S123, a test signal is provided for verifying the operability of the bond created between the semiconductor die 18 and the substrate 12. In differing embodiments of the present invention, it is understood that the test signal provided in step S123 would vary depending upon the application and type of semiconductor die 18 used. For example, the test signal may be electrical current, radio waves, or some other type of input to verify that the semiconductor die 18 is connected to the electrical leads 14 and thus the substrate 12.

After the die positioning system 10 has been successfully tested, a protective coating is deposited over the semiconductor die 18 and the die positioning structure 16 in step S124. The protective layer 22 is preferably composed of non-conductive material and disposed over the die positioning structure 16, the semiconductor die 18, and the bonds 26a, 26b to increase the resiliency and ruggedness of the die positioning system 10. Preferably, the protective layer 22 is treated with a blocking pigment to optically shield the semiconductor die 18 from photovoltaic action. Step S126 represents the termination of the method of bonding a semiconductor die to a substrate, but it is understood that the method can be repeated continuously to generate a large stock of semiconductor devices suitable for use across an array of commercial enterprises.

The present invention as described in its preferred embodiments thus improves the procedure of manufacture of electronic devices in addition to providing a specific method for the manufacture of a novel die positioning system. In particular, the formation of the die positioning structure by systematic and reliable means on a selected substrate will significantly reduce the costs and burdens of semiconductor packaging. Moreover, by electron beam curing the die positioning structure (as well as the underfill 24, the protective overcoat 22, etc.), the pace of production of the die positioning systems can be significantly increased, permitting the use of die positioning systems in an ever-broadening field of commercial applications. For example, typical cure times for electron curables are tens of milliseconds, whereas the typical cure times for their thermal equivalents may be many seconds.

It should be apparent to those skilled in the art that the above-described embodiments are merely illustrative of but a few of the many possible specific embodiments of the present invention. Numerous and various other arrangements can be readily devised by those skilled in the art without departing from the spirit and scope of the invention as defined in the following claims.

We claim:

1. A method of bonding a semiconductor die to a substrate, the method comprising:
providing a substrate having at least one lead disposed thereon;
providing an E-beam curable material;
providing a negative cast of a die positioning structure;
pressing the E-beam curable material between the substrate and the negative cast, thereby providing a die positioning structure;
curing the E-beam curable material by E-beam irradiation through the substrate, thereby providing a cured die positioning structure; and
bonding a semiconductor die within the cured die positioning structure.

2. The method of claim 1 wherein the step of curing the second material comprises irradiating the second material with an electron beam having an energy of between 100 and 300 kiloelectron volts.

3. The method of claim 1 wherein the step of curing the second material comprises irradiating the second material with an electron beam having an energy of 200 kiloelectron volts.

4. The method of claim 1 wherein the E-beam curable material is selected from the group consisting of acrylates, urethanes, acrylated urethanes, epoxies, or metal-doped epoxies.

5. The method of claim 1 wherein the E-beam curable material is an insulator.

6. The method of claim 1 wherein the E-beam curable material is a conductor.

7. The method of claim 1 wherein the E-beam curable material is an acrylated urethane.

8. The method of claim 1 wherein the E-beam curable material is an epoxy.

9. The method of claim 1 wherein the E-beam curable material is a metal-doped epoxy.

10. The method of claim 1 wherein the step of providing a negative cast of a die positioning structure comprises providing a platen.

11. The method of claim 1 wherein the step of providing a negative cast of a die positioning structure comprises providing a platen disposed for repeated pressing of the negative cast of the die positioning structure.

12. The method of claim 1 wherein the step of bonding the semiconductor die within the cured die positioning structure comprises applying bonding adhesives to at least one lead contact point.

13. The method of claim 1 wherein the semiconductor die is one of a read-only memory chip, an electrically programmable read-only memory chip, or an electrically erasable programmable read-only memory chip.

14. The method of claim 1 further comprising the step of providing a non-conductive protective layer protecting the semiconductor die and the die positioning structure.

15. The method of claim 1 further comprising the step of introducing light-blocking pigments into the second material.

16. A die positioning system comprising:
a substrate having a plurality of electrical leads formed thereon;
a die positioning structure disposed on the substrate, the die positioning structure adapted to receive a semiconductor die; and
wherein the die positioning structure is comprised of an E-beam curable material.

17. The die positioning system of claim 16 wherein the E-beam curable material is selected from the group consisting of acrylates, urethanes, acrylated urethanes, epoxies, or metal-doped epoxies.

18. The die positioning system of claim 16 wherein the E-beam curable material is an insulator.

19. The die positioning system of claim 16 wherein the E-beam curable material is a conductor.

20. The die positioning system of claim 16 wherein the E-beam curable material is an acrylated urethane.

21. The die positioning system of claim 16 wherein the E-beam curable material is an epoxy.

22. The die positioning system of claim 16 wherein the E-beam curable material is a metal-doped epoxy.

23. An electronic device comprising:
a substrate having a plurality of electrical leads formed thereon,
a die positioning structure disposed on the substrate, the die positioning structure comprised of an electron-beam curable material and adapted to receive a semiconductor die; and
a semiconductor die having a plurality of bonding pads, the semiconductor die disposed within the die positioning structure and electrically connected to the plurality of electrical leads.

24. The electronic device of claim 23 wherein the E-beam curable material is selected from the group consisting of acrylates, urethanes, acrylated urethanes, epoxies, or metal-doped epoxies.

25. The electronic device of claim 23 wherein the E-beam curable material is an insulator.

26. The electronic device of claim 23 wherein the E-beam curable material is a conductor.

27. The electronic device of claim 23 wherein the E-beam curable material is an acrylated urethane.

28. The electronic device of claim 23 wherein the E-beam curable material is an epoxy.

29. The electronic device of claim 23 wherein the E-beam curable material is a metal-doped epoxy.

30. The electronic device of claim 23 further comprising a non-conductive protective layer disposed on the semiconductor die and the die positioning structure.
